(19) United States
(12) Patent Application Publication
(10) Pub. No.: US 2012/0161599 A1
(43) Pub. Date: Jun. 28, 2012

(54) SERVER HOLDER

(75) Inventors: HSUAN-CHANG CHEN, Tu-Cheng (TW); CHIA-MING CHANG, Tu-Cheng (TW); PING-HUNG CHEN, Tu-Cheng (TW)

(73) Assignee: HON HAI PRECISION INDUSTRY CO., LTD., Tu-Cheng (TW)

(21) Appl. No.: 13/090,230

(22) Filed: Apr. 19, 2011

(30) Foreign Application Priority Data
Dec. 24, 2010 (TW) 99145954

(51) Int. Cl. H05K 7/14

(52) U.S. Cl. 312/333

(57) ABSTRACT

An anti-drop structure includes a rail assembly, a drag assembly, and two latching members. The rail assembly includes a pair of L-shaped sliding rails. Each L-shaped sliding rail includes a sidewall and a holding portion bent outwards from an end of the sidewall. One end of the sidewall defines a latching opening. The drag assembly is slidably positioned on the holding portions of the sliding rails and located between the sidewalls of the sliding rails. The drag assembly includes two opposite side plates. Each latching member is positioned on an inner surface of a corresponding one of the side plates, and includes a latching portion passing through a corresponding side plate. The latching portion is configured to slid into a corresponding latching opening to prevent the drag assembly from dropping out of the rail assembly.

### BACKGROUND

1. Technical Field

The disclosure relates to a server holder for holding computer servers.

2. Description of Related Art

Computer servers typically include a server holder formed by a pair of first L-shaped sliding rails, a server module is received in the holder, and a server bracket includes a pair of second L-shaped sliding rails corresponding to the first L-shaped sliding rails in shape and size. The pair of second sliding rails is respectively fixed on two opposite sidewalls of the server bracket. The holder generally is movably received on the server bracket by the first and second L-shaped sliding rails. Since the holder and the serve is heavy, and has no structure to protect it from being dropped, when operators want to remove the server from the server bracket, if excessive force is used to remove it, the sever may accidentally fall from the server bracket, which not only damages the server, but also may injure the operators.

What is needed, therefore, is a server holder to overcome the above-described problem.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure.

FIG. 1 is an assembled, schematic view of a server holder, according to an exemplary embodiment.

FIG. 2 is an exploded, schematic view of the server holder of FIG. 1.

FIG. 3 is an enlarged view of a circled portion A of FIG. 2.

FIG. 4 is an assembled, schematic view of a latching member of the server holder of FIG. 1.

FIG. 5 is an exploded, schematic view of the latching member of FIG. 4.

### DETAILED DESCRIPTION

Embodiments of the disclosure will now be described in detail below, with reference to the accompanying drawings.

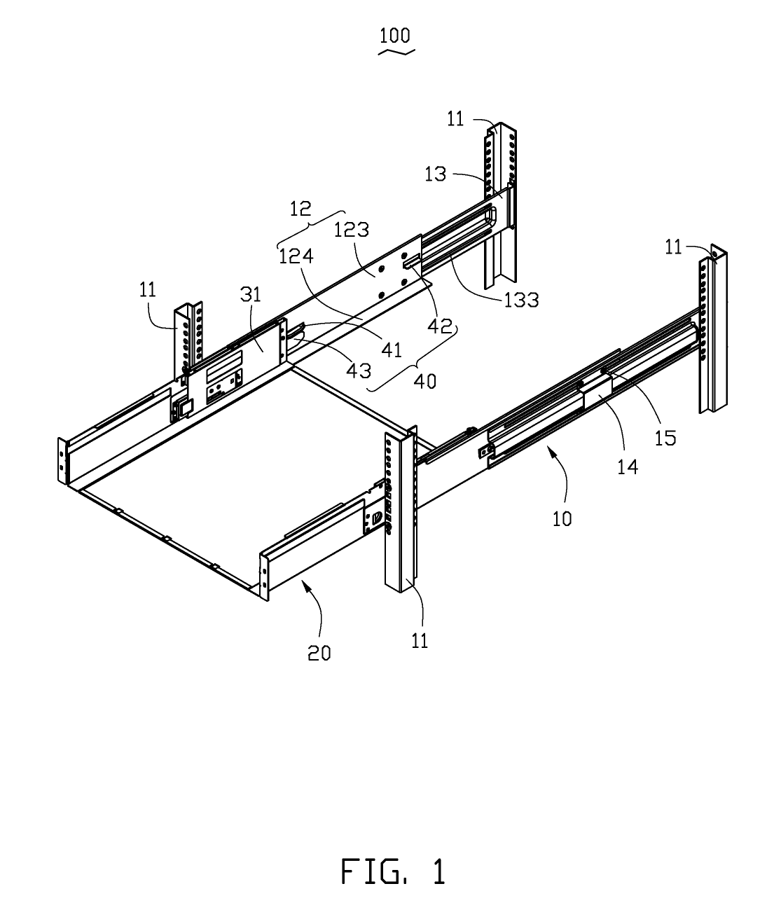

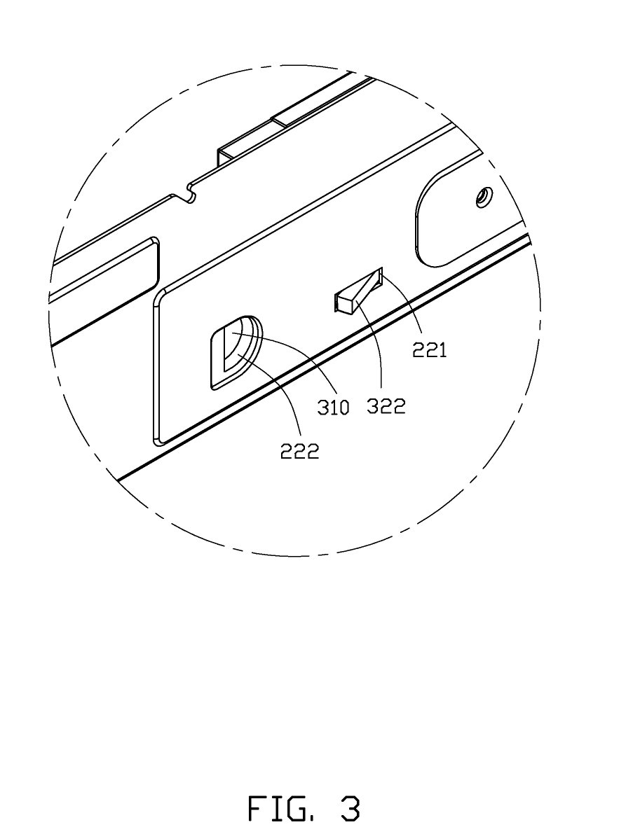

Referring to FIGS. 1-3, a server holder 100, according to an embodiment, includes a rail assembly 10, a drag assembly 20, two latching members 30, and an anti-tilt assembly 40.

The rail assembly 10 includes two pairs of columns 11, a pair of L-shaped sliding rails 12, a pair of guiding rails 13, two fixing members 14, and a number of screws 15. The two pairs of columns 11 cooperatively form a parallelogram, with the columns 11 respectively located at the four corners of the parallelogram. In this embodiment, the parallelogram is a rectangle. Each sliding rail 12 includes a first connecting end 121 and a second connecting end 122 away from the first connecting end 121. Each guiding rail 13 includes a third connecting end 131 and a fourth connecting end 132 away from the third connecting end 131. The two first connecting ends 121 are each connected to a corresponding column 11. Each first connecting end 121 defines a latching opening 1210. Each second connecting end 122 defines two pairs of first threaded holes 1220. Each guiding rail 13 defines two parallel guiding slots 133 extending along a lengthwise direction of the guiding rails 13. Each of the two fixing members 14 defines two pairs of second threaded holes 140 corresponding to the first threaded holes 1220 of the sliding rail 12 in shape and size.

In assembly of the rail assembly 10, both the first threaded holes 1220 of the sliding rail 12 and the second threaded holes 140 of the fixing member 14 are aligned with the guiding slots 133 of the guiding rail 13. The guiding rail 13 is sandwich between the fixing member 14 and the sliding rail 12. Each screw 15 passes through a corresponding first threaded hole 1220, a corresponding guiding slot 133, and a corresponding second threaded hole 140 to secure the fixing member 14, the guiding rail 13 and the sliding rail 12 together. The diameter of each screw 15 is smaller than the width of the guiding slot 133, thereby the sliding rail 12 is capable of sliding along the guiding slot 133.

The pair of L-shaped sliding rails 12 cooperatively form a receiving room for receiving the drag assembly 20. Each sliding rail 12 includes a sidewall 123 and a holding portion 124 bent outward from an end of the sidewall 123 about 90 degrees. The drag assembly 20 is slidably positioned on the holding portions 124 of the siding rails 12.

The drag assembly 20 includes a bottom plate 21 and two side plates 22. The bottom plate 21 is substantially rectangular in shape. The two side plates 22 are substantially parallel to each other and perpendicularly connect to two opposite edges of the bottom plate 21. Each side plate 22 defines a through hole 221 substantially at the center thereof and a first operating opening 222. The through hole 221 and the first operating opening 222 are arranged in a line that is substantially parallel to the lengthwise direction of the corresponding side plate 22. The through hole 221 is an elongated slot.

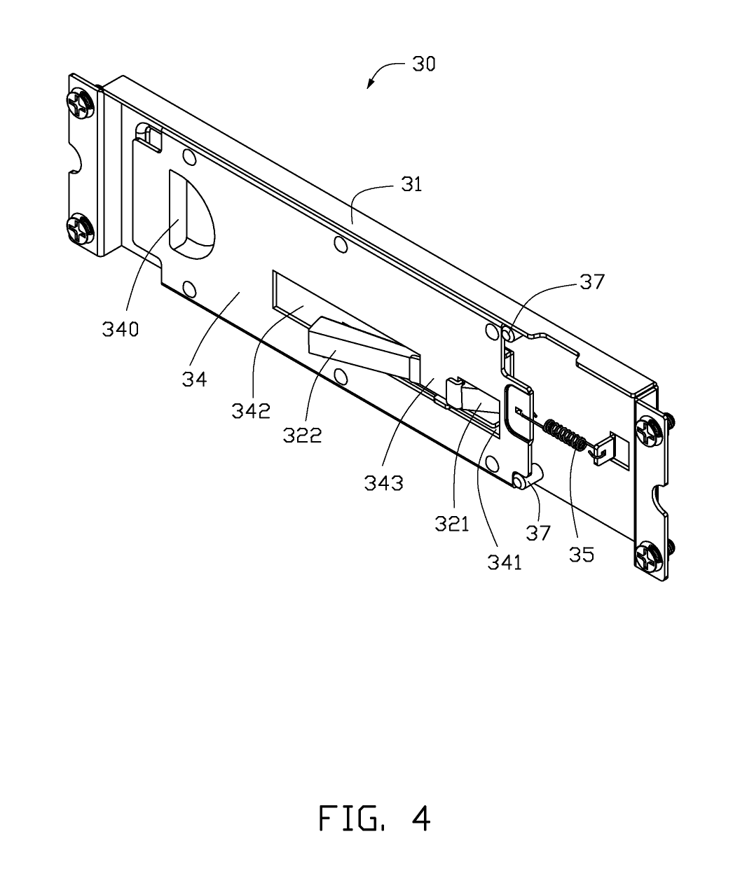

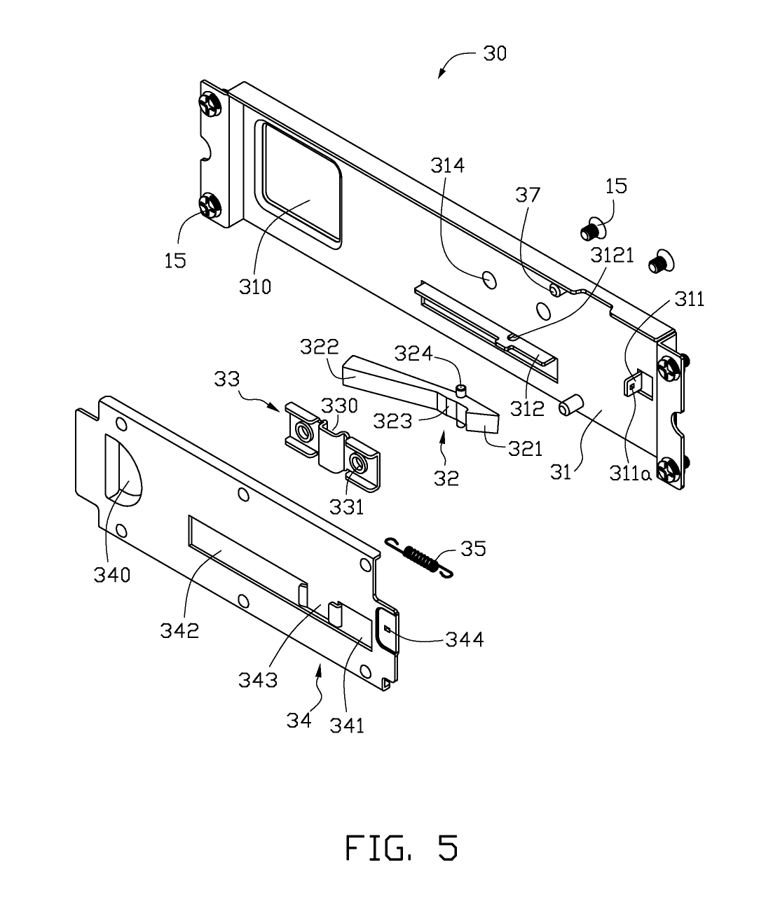

Also referring to FIGS. 4-5, each latching member 30 is positioned on an inner surface of the side plate 22. The two latching openings 1210 each corresponding to a different latching member 30. Each latching member 30 includes a cover plate 31, a latching portion 32, a fixing portion 33, an operating plate 34, and an elastic member 35.

The cover plate 31 defines a second operating opening 310 corresponding to the first operating opening 222 of the side plate 22, and includes a flange 311 away from the second operating opening 310 and bent outward from an inner sidewall of the cover plate 31 about 90 degrees. The flange 311 defines a first slot 311a. The cover plate 31 also includes a first extending member 312 and two second extending members 37. The first extending member 312 and the two second extending members 37 are bent outward from an inner sidewall of the cover plate 31 about 90 degrees and positioned between the flange 311 and the second operating opening 310. The second extending members 37 are positioned at two opposite sides of the first extending member 312. The first extending member 312 defines a latching slot 3121. The inner sidewall of the cover plate 31 also defines a pair of third threaded holes 314. The pair of third threaded holes 314 are arranged in a line that is substantially parallel to the lengthwise direction of the cover plate 31, and positioned between the first extending member 312 and one of the second extending members 37.

The latching portion 32 is substantially an elongated strip and includes a hooking part 321, and a latching part 322 away from the hooking part 321 and bent outward from the hooking part 321 at an angle. The latching portion 32 defines a groove 323 between the hooking part 321 and the latching part 322, and includes a pair of pivots 324. Each pivot 324 perpendicularly extends upward from a sidewall of the latching portion 32 and is close to the hooking part 321.

The fixing portion 33 includes a pair of fourth threaded holes 331 corresponding to the third threaded hole 314 of the cover plate 31a in shape and size, and forms a fixing slot 330 between the pair of fourth threaded holes 331.

The operating plate 34 defines a third operating opening 340 corresponding to the second operating opening 310, a first opening 341 corresponding to the hooking part 321 of the latching portion 32, a second opening 342 corresponding to the latching part 322 of the latching portion 32. The first opening 341 and the second opening 342 are arranged on a line that is substantially parallel to the lengthwise direction of the operating plate 34. The second opening 342 is an elongated opening extending along a lengthwise direction of the operating plate 34. A connecting plate 343 is positioned between the first opening 341 and the second opening 342. The operating plate 34 also defines a second slot 344 corresponding to the first slot 311a of the cover plate 31.

In this embodiment, the elastic member 35 is a spring.

In assembly of the latching members 30, first, one of the pivots 324 of the latching portion 32 is rotatably received in the latching slot 3121 of the first extending member 312. Then the fourth threaded holes 331 of the fixing portion 33 are aligned with the third threaded hole 314 of the cover plate 314. The fixing portion 33 is assembled to the cover plate 31 by inserting the screws 15 through the fourth threaded holes 331 and the third threaded holes 314 correspondingly. The other pivot 324 of the latching portion 32 is rotatably received in the fixing slot 330 of the fixing portion 33. As such, the latching portion 32 is capable of rotating about the latching slot 3121 and the fixing slot 330. Then the operating plate 34 is covered by the cover plate 31 with the hooking part 321 passing through the first opening 341 and the latching part 322 passing through the second opening 342. Finally, one end of the elastic member 35 is hooked to the first slot 311a of the cover plate 31 and the other end is hooked to the second slot 344 of the operating plate 34. The connecting plate 343 is received in the groove 323.

The two latching members 30 are respectively positioned on the inner sidewalls of the side plates 22 of the drag assembly 20. The operating plate 34 is sandwiched between the cover plate 31 and the side plate 22 of the drag assembly 20, and the latching part 322 also passes through the through hole 221 of the side plate 22. The first operating opening 222, the second operating opening 310 and the third operating opening 340 are aligned with each other.

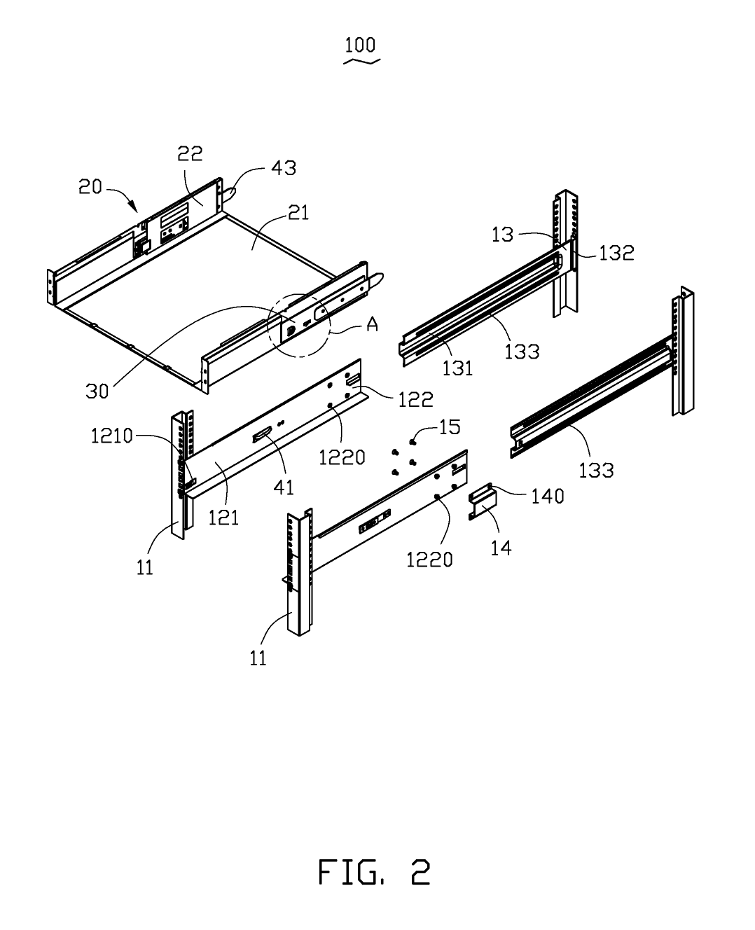

Referring back to FIGS. 1 and 2, the anti-tilt assembly 40 includes two first blocks 41, two second blocks 42, and two blocking plates 43. Each first block 41 is positioned on the sidewall 123 of the sliding rails 12, and is positioned between the first threaded holes 1220 and the latching opening 1210. In this embodiment, the first block 41 is positioned at the middle of the sidewall 123. Each second block 42 is positioned on one end of the sidewall 123 of the sliding rails 12 close to the second connecting end 122. Each blocking plate 43 is extended along the lengthwise direction of the side plate 22 of the drag assembly 20 and away from the latching opening 1210.

In the original state, the drag assembly 20 is positioned on the holding portions 124 with each blocking plate 43 resisting against a corresponding second block 42. The operating plate 34 resists against the second extending members 37. In use, the drag assembly 20 is pulled until the latching part 322 of the latching portion 32 is slid into a corresponding latching opening 1210, at the same time, each blocking plate 43 resists against a corresponding first block 41. Therefore, the engagement of the latching opening 1210 and the latching part 322 can prevent the drag assembly 20 from sliding out of the sliding rail 12, and the engagement of the blocking plate 43 and the first block 41 can prevent the drag assembly 20 from tilting. Then, if operators want to pull the drag assembly 20 out of the sliding rail 12, by pulling the operating plate 34 through the third operating opening 340 along the direction of away from the elastic member 35. The connecting plate 343 elastically presses the latching part 322 backward until the latching part 322 disengages with the latching opening 1210, as such, the last half of the drag assembly 20 is capable of being pulled out of the rail assembly 10.

The number and the arrangement of the first threaded holes 1220 in each holding portion 124, and the second threaded holes 140 in each fixing member 14 are not limited to this embodiment but can be set depending on demands. The number and the arrangement of the third threaded holes 314 in the cover plate 31a and the fourth threaded holes 331 in the fixing portion 33 are not limited to this embodiment but can be set depending on demand. Further, in other embodiments, other fasteners can be employed instead of the screws 15.

The number and the arrangement of the second extending members 37 can be changed depending on demand as well. In other embodiments, the second extending members 37 can be omitted.

In other embodiments, the fixing portion 33 can be attached to the inner sidewall of the cover plate 31 by other fasteners.

While certain embodiments have been described and exemplified above, various other embodiments will be apparent to those skilled in the art from the foregoing disclosure. The disclosure is not limited to the particular embodiments described and exemplified, and the embodiments are capable of considerable variation and modification without departure from the scope of the appended claims.

What is claimed is:

1. A server holder comprising:
a rail assembly comprising a pair of L-shaped sliding rails, each L-shaped sliding rail comprising a sidewall and a holding portion bent outwards from an end of the sidewall, one end of the sidewall defining a latching opening;
a drag assembly slidably positioned on the holding portions of the sliding rails and located between the sidewalls of the sliding rails, the drag assembly comprising two opposite side plates; and
two latching members, each latching member being positioned on an inner surface of a corresponding one of the side plates, each latching member comprising a latching portion, each latching portion passing through a corresponding side plate and being configured to slid into a corresponding latching opening to prevent the drag assembly from dropping out of the rail assembly.

2. The server holder of claim 1, wherein the rail assembly further comprises two pairs of columns and a pair of guiding rails, the two pairs of columns are arranged in a parallelogram, each sliding rail comprises a first connecting end and a second connecting end away from the first connecting end, each guiding rail comprises a third connecting end and a fourth connecting end away from the third connecting end, each first connecting end is connected to a corresponding column, each second connecting end is slidably connected to a corresponding third connecting end, each fourth end is connected to a corresponding column.

3. The server holder of claim 2, wherein the parallelogram is a rectangle.

4. The server holder of claim 2, wherein one end of each sliding rail close to the second connecting end defines two pairs of first threaded holes, each guiding rail defines two parallel guiding slots extending along a lengthwise direction of the guiding rail, the rail assembly further comprises two fixing members and eight first screws, the two fixing members each defines two pairs of second threaded holes, each pair first threaded holes is aligned with a corresponding pair of second threaded holes and a corresponding guiding slot, each first screw passes through a corresponding first threaded hole, a corresponding guiding slot, and a corresponding second threaded hole such that each guiding rail is assembled between a corresponding fixing member and a corresponding sliding rail.

5. The server holder of claim 4, wherein a diameter of each first screw is smaller than the width of each guiding slot, each sliding rail is capable of sliding along the guiding slots of a corresponding guiding rail.

6. The server holder of claim 4, wherein each side plate defines a through hole and a first operating opening, the through hole and the first operating opening are arranged in a line that is substantially parallel to the lengthwise direction of each side plate, the through hole is an elongated slot and positioned close to a corresponding guiding rail, the first operating opening is positioned away from the corresponding guiding rail; each latching member further comprises a cover plate, a fixing portion, and an operating plate, the cover plate defines a second operating opening aligned with the first operating opening, the cover plate further comprises a first extending member defining a latching slot, the fixing portion is attached on an inner sidewall of the cover plate and defines a fixing slot corresponding to the latching slot, the latching portion comprises a hooking part, a latching part, and a pair of pivots, the latching part bends outwards from the hooking part at an angle, each pivot perpendicularly extends from a sidewall of the latching portion and is close to the hooking part, one of the pivot is rotatably received in the latching slot, the other pivot is rotatably received in the fixing slot, the operating plate defines a first opening corresponding to the hooking part and a second opening corresponding to the latching part, the operating plate is positioned on the cover plate, with the hooking part passing through the first opening and the latching part passing through the second opening; the hooking part of each latching portion passes through the through hole of a corresponding side plate and is configured to slid into a corresponding latching opening to prevent the drag assembly from dropping out of the rail assembly.

7. The server holder of claim 6, wherein the operating plate defines a third operating opening aligned with the first and second operating openings.

8. The server holder of claim 6, wherein each latching member comprises two second screws, the cover plate defines a pair of third threaded holes, the fixing portion defines a pair of fourth threaded holes aligned with the third threaded holes, the fixing portion is assembled to the cover plate by inserting the two second screws through the fourth threaded holes and the third threaded holes.

9. The server holder of claim 6, wherein each latching member further comprises a spring, the cover plate comprises a flange away from the second operating opening and bending outwards from an inner sidewall of the cover plate about 90 degrees, the flange defines a first slot, the operating plate also defines a second slot corresponding to the first slot, one end of the spring is hooked to the first slot and the other end is hooked to the second slot.

10. The server holder of claim 9, wherein the cover plate comprises two second extending members, the second extending members are positioned at two opposite sides of the first extending member close to the flange and configured to resist against one end of the operation plate.

11. The server holder of claim 6, wherein the operating plate comprises a connecting plate positioned between the first opening and the second opening; the latching portion defines a groove between the hooking part and the latching part; the connecting plate is received in the groove.

12. The server holder of claim 2, further comprising an anti-tilt assembly, wherein the anti-tilt assembly comprises two first blocks and two blocking plates, each first block is positioned on the sidewall of each sliding rail, each blocking plate is positioned on one end of a corresponding side plate away from a corresponding latching opening along the lengthwise direction of the corresponding side plate, each blocking plate is configured to resist against a corresponding first block to prevent the drag assembly from tilting relative to the rail assembly.

13. The server holder of claim 12, wherein the anti-tilt assembly comprises two second blocks, each second block is positioned on another end of the corresponding sidewall; each blocking plate is configured to resist against a corresponding second block to prevent the drag assembly from tilting relative to the rail assembly.

14. The server holder of claim 1, wherein the holding portion is bent outwards from the end of the sidewall about 90 degrees.

15. The server holder of claim 1, wherein the drag assembly further comprises a bottom plate, the bottom plate is substantially rectangular in shape, the two side plates are substantially parallel to each other and perpendicularly connect to two edges of the bottom plate.
